(19) United States
(12) Patent Application Publication
(10) Pub. No.: US 2014/0168907 A1
(43) Pub. Date: Jun. 19, 2014

(54) OVERHEAD PANEL FOR AN AIRCRAFT COCKPIT AND AIRCRAFT INCLUDING SUCH A PANEL

(71) Applicant: Bernard Guering, Montrabe (FR)

(72) Inventor: Bernard Guering, Montrabe (FR)

(73) Assignee: AIRBUS OPERATIONS (S.A.S.), Toulouse (FR)

(21) Appl. No.: 13/978,243

(22) PCT Filed: Jan. 10, 2012
(86) PCT No.: PCT/FR12/50064

§ 371 Date: Jan. 10, 2014

(30) Foreign Application Priority Data
Jan. 12, 2011 (FR) 11 50248

(51) Int. Cl. H05K 5/00; H05K 13/00; H05K 5/02

(52) U.S. Cl. CPC H05K 5/0017; H05K 5/0247; H05K 13/00
USPC 361/730; 29/825

(57) ABSTRACT

The invention relates to an overhead panel able to be positioned in an aircraft cockpit, which includes an assembly of independent submodules (67), each of which is associated with a particular system or a particular function of the aeroplane, incorporated in a rigid self-supporting module (60), including a front face (65) to which the submodules (67) are attached, and two side faces fitted with peripheral electrical connectors (63) intended to be connected to different systems of the aeroplane.

The invention also relates to a method of manufacture of such a panel.

### TECHNICAL FIELD

The invention relates to an overhead panel for an aircraft cockpit and an aircraft including such a panel.

In the remainder of the document, for the sake of simplification of the description, an aircraft of the aeroplane type is considered.

### STATE OF THE PRIOR ART

The invention is involved in a context of a search for overall improvement of aeroplanes' nose sections. In this context, all the major components of the cockpits, as described for example in the document entitled [1] “Cockpit-ATA100 Chapter 25-10-20” (“Airbus A340/A330 System description note”, Sep. 15, 1993), are concerned, notably the overhead panel located above the pilots, the role of which is to give a simplified instantaneous status of the aeroplane's main systems.

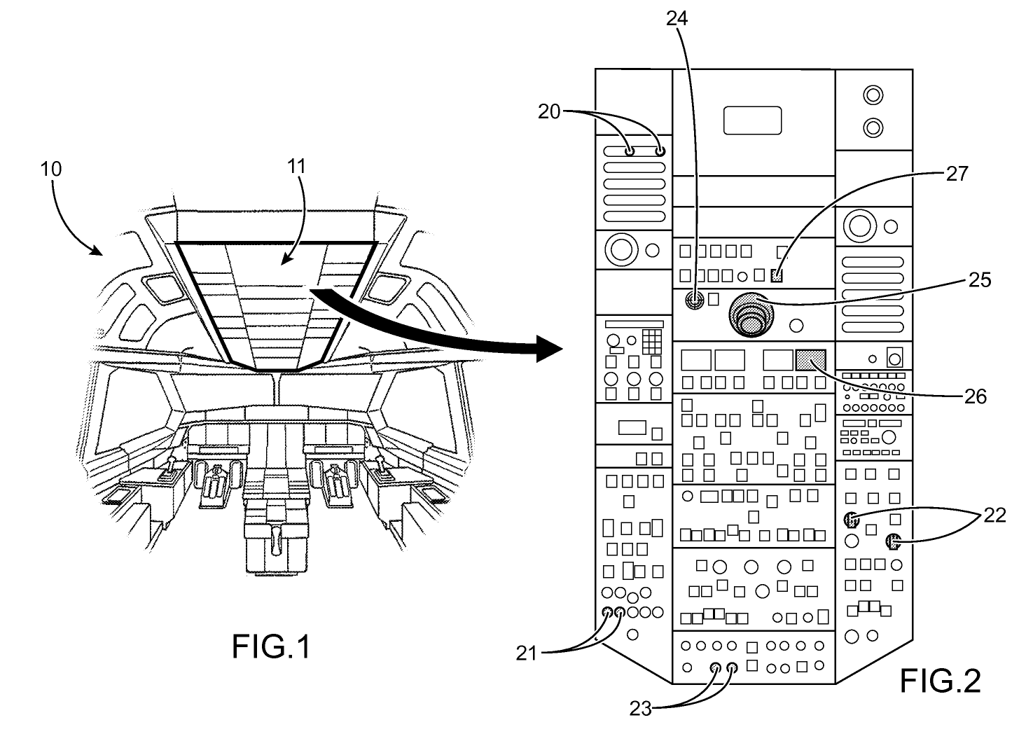

Such an overhead panel 11, which is illustrated in FIGS. 1 and 2 respectively in an aeroplane cockpit 10, as seen from the front, consists of independent submodules. Each submodule is associated with a particular system or with a particular function. This may, for example, be:
a circuit breaker 20,
a pushbutton 21,
a multi-position selector dial 22,
an inverter 23,
a beeper 24,
a reading light 25,
a fire pull handle 26,
a multi-stage pushbutton light 27.

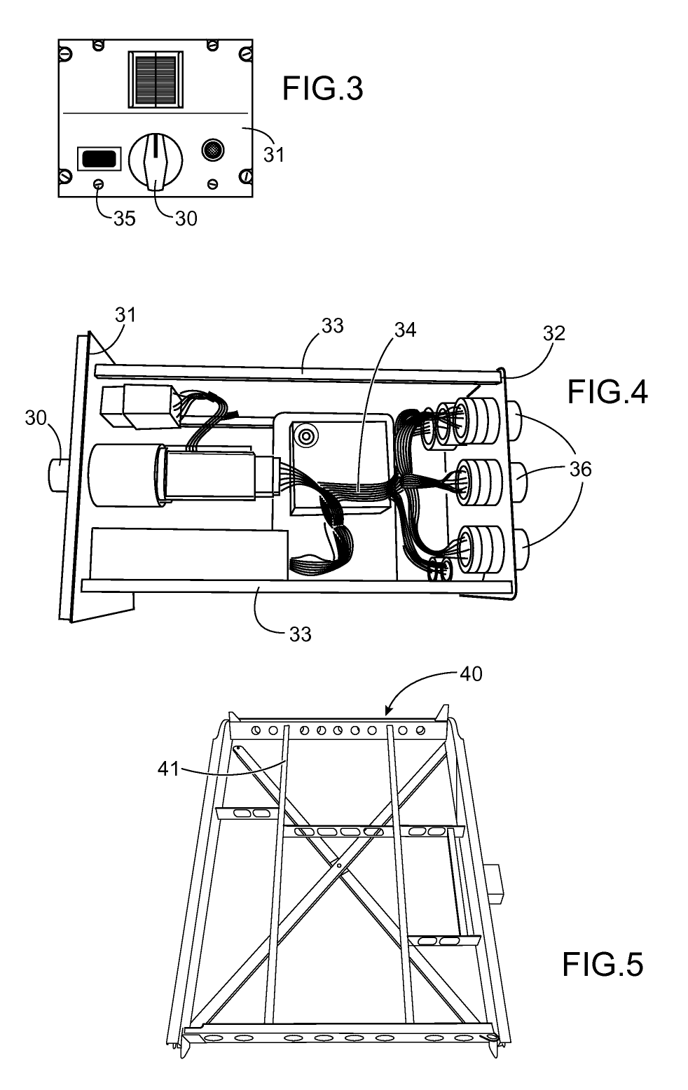

It covers an area of approximately 100 mm×600 mm. As illustrated in FIGS. 3 and 4, each submodule, in this case a multi-position selector dial 30, includes a front plate 31 and a rear plate 32, connected together by small columns 33. On front plate 31 quick-release fasteners 34 of the said submodule and fasteners 35 of an illuminated label, for example a plexiglass plate which is etched and illuminated from within, or a luminescent plate, are represented. Each submodule 30 is connected to one or more rear connectors 36, attached to rear plate 32, by a connection harness 34. Such a harness 34 is wired, with the rear plate swivelled through 180°.

The submodules assembly is attached to a support frame 40, fitted with attachment strips 41, as illustrated in FIG. 5. This support frame is itself attached rigidly to a drip shield, closely following the shape of the fuselage, which forms a protective shell positioned as close as possible to the structure of the aeroplane to resolve the technical problems posed by bird strikes on the cabin, by vibrations, by dripping water (condensation on the ceiling structure), and through fretting of the contacts.

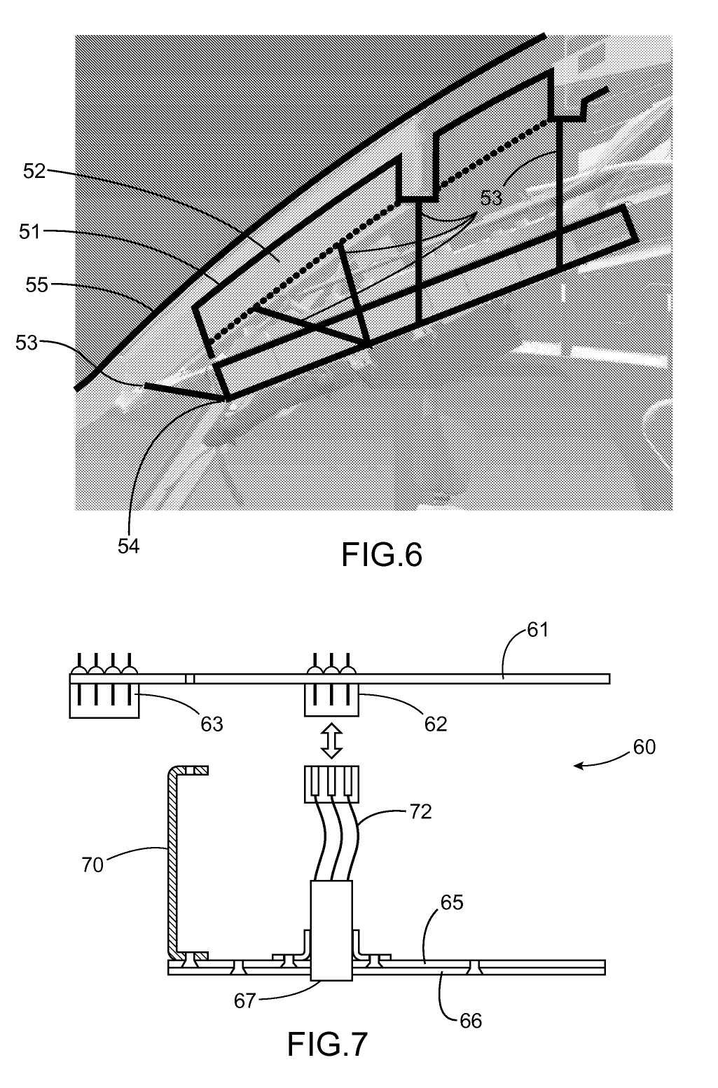

FIG. 6 illustrates, in the structure of the aeroplane, this drip shield 51, volume 52 dedicated to storage of wiring, where the face of the structural attachment connecting rods 53 allows a rigid connection between this drip shield 51 and support frame 54 of the overhead panel. Reference 55 illustrates the area sensitive to bird strikes.

The overhead panel of the prior art has many disadvantages:
being complex to produce (too many modules and too many parts required for its assembly) and is therefore costly,
demanding volume (need for a drip shield for attachment to the structure of the aeroplane) and high weight,
delicate installation (accessibility of wiring) which is difficult to inspect,
aerodynamic constraint (essential requirement in designing a shape of an aeroplane nose section),
electrical segregation (1/2),
substantial additional wiring length (problem of storage in rear area) and storage of wiring in blind fashion.

The object of the invention is to overcome all these disadvantages in a radical fashion by incorporating into a single module an assembly which has hitherto consisted of multiple elements positioned on an independent frame.

### DESCRIPTION OF THE INVENTION

The invention relates to an overhead panel able to be positioned in an aircraft cockpit, characterised in that it includes an assembly of independent submodules, each of which is associated with a particular system or a particular function of the aeroplane, incorporated in a rigid self-supporting module, for example of parallelepipedic shape and less than 100 mm thick, including a front face to which the submodules are attached, and two side faces fitted with connectors intended to be connected to different systems of the aeroplane.

The self-supporting module advantageously includes:
a rear plate including an integrated circuit plate to which central electrical connectors and peripheral connectors are welded,
a front plate, to which the submodules are attached,
a perimeter frame providing the junction between these two rear and front plates, over the entire periphery of the module;
standard micro-harnesses, each enabling a connection to be made between a submodule and a central connector positioned on the rear plate.

Advantageously, an illuminated label is positioned on the front plate.

Advantageously, the front plate includes a metal sheet in which weight reduction and accessibility holes are made.

Advantageously, the overhead panel includes dampening pins positioned on the rear surface of the rear plate, for example in each of the corners of this rear surface.

Advantageously, the rear plate may include an integrated circuit plate the final layer of which is an anti-condensation layer, or a small panel made of thermoplastic material.

The invention also relates to a method for manufacturing the overhead panel which includes the following steps:
integration of the mini-harnesses on the submodules,
clipping of each of these mini-harnesses on the corresponding central connectors previously welded on the integrated circuit plate,
attachment of the assembly formed in this manner to the perimeter frame,
docking of the front plate, ensuring that each of the submodules is centred in a corresponding recess of the front plate,
attachment of the submodules, on the front plate through the rear face.

The overhead panel of the invention has the following advantages:
Production as a rigid self-supporting module (6 working faces) including a rear plate consisting of an integrated circuit, a front plate, where these plates are connected to one another by a perimeter frame, an illuminated label attached to the front plate, where all the submodules are attached to the front plate, where all the connection components are welded (one operation) on the rear plate, and standardised, prefabricated interface mini-harnesses connect the submodules and the connection components,
elimination of the frame of the prior art,
elimination of the drip shield,
secure wiring, with direct access, and no excess lengths,
flexible installation with four dampeners (anti-impact and anti-vibration protection),
high-density circuit-breaker connectors positioned laterally (direct access to the attachments, segregation of the system),
integrated drip protection,
reduction of the overall volume (elimination of the frame/constant thickness less than 100 mm).

### BRIEF DESCRIPTION OF THE ILLUSTRATIONS

FIGS. 1 and 2 illustrate an overhead panel of the prior art positioned respectively in the cockpit of an aeroplane and as seen from the front,

FIGS. 3 and 4 illustrate a submodule of the overhead panel of the prior art,

FIG. 5 illustrates the frame mount of the overhead panel of the prior art,

FIG. 6 illustrates the attachment of the overhead panel of the prior art to the structure of the aeroplane,

FIG. 7 illustrates a partial schematic view of the overhead panel of the invention,

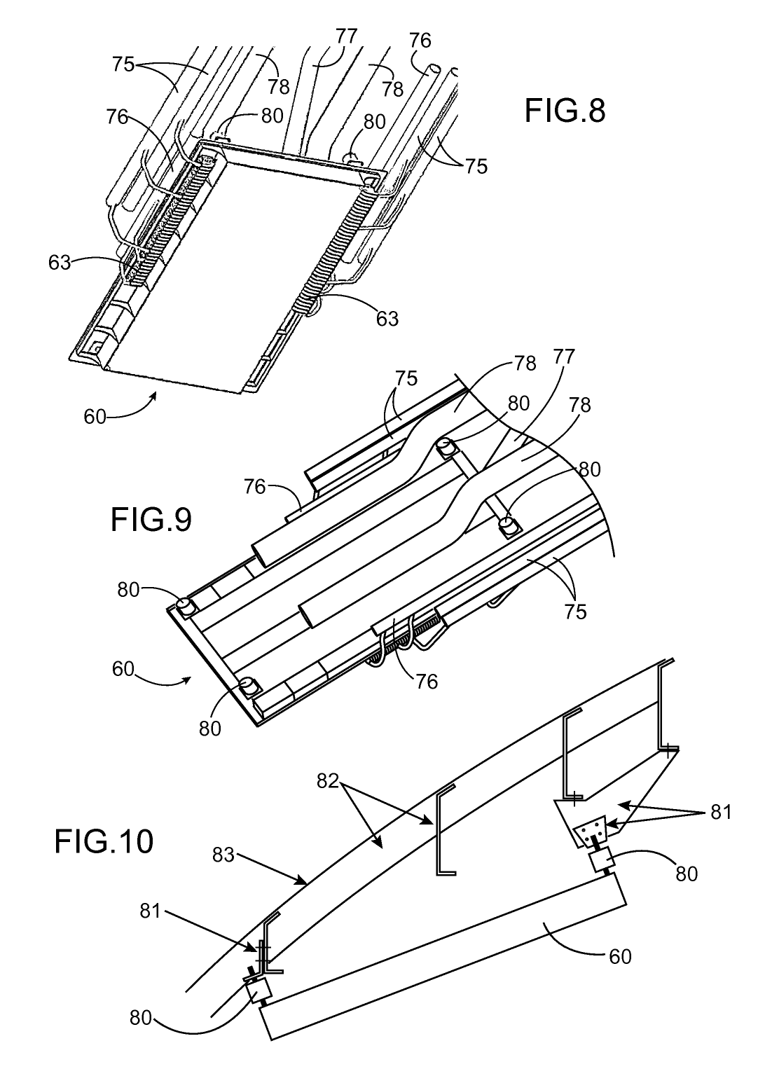

FIGS. 8 and 9 illustrate the overhead panel of the invention, respectively as a top view and bottom view,

FIG. 10 illustrates the attachment of the overhead panel of the invention to the structure of an aeroplane,

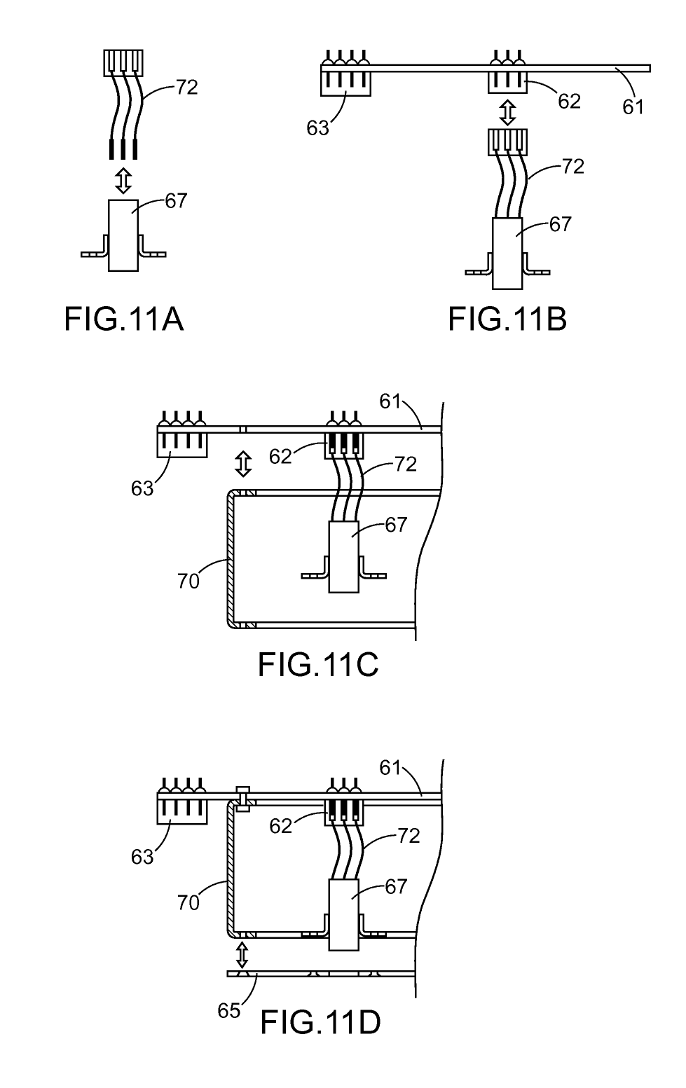

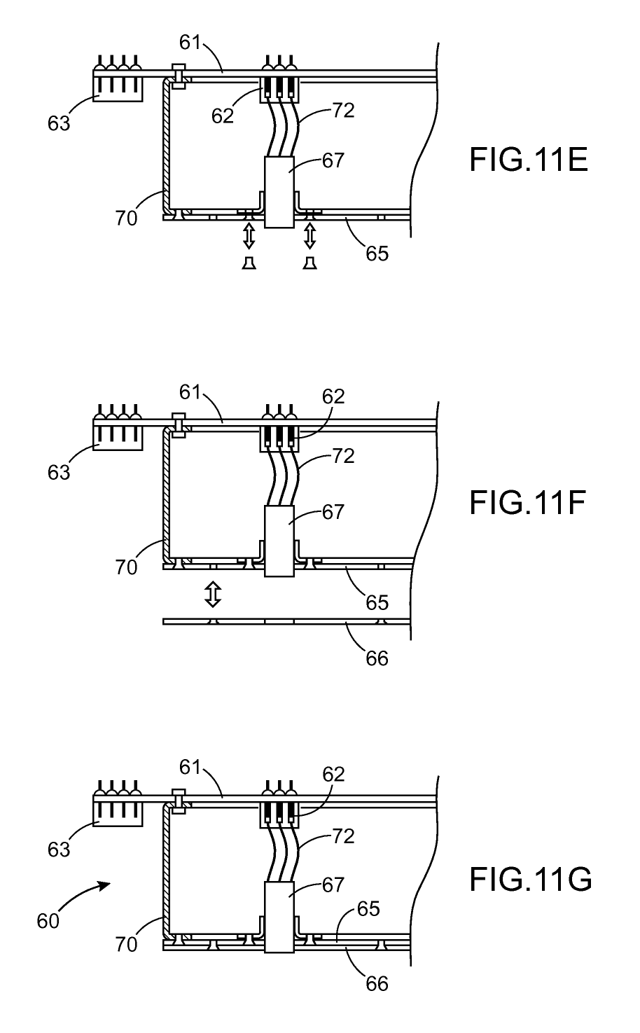

FIGS. 11A to 11G illustrate the different steps of assembly of the overhead panel of the invention.

### DETAILED DESCRIPTION OF PARTICULAR EMBODIMENTS

As illustrated in FIG. 7, the overhead panel of the invention 60 includes a rigid self-supporting module formed of:
a rear plate 61 including an integrated circuit plate on which are welded central electrical connectors 62 intended to be connected to submodules 67, and peripheral electrical connectors 63 intended to be connected to the different systems of the aeroplane,
a front plate 65, which is formed from a metal sheet to which are attached submodules 67 (in this case, a pushbutton), previously described in the device of the known art, where an illuminated label, which can be illuminated, is positioned on the front face of this front plate,
a perimeter frame 70 forming the junction between these two rear and front plates, over entire periphery of the module;
standard micro-harnesses 72, each enabling a connection to be made between a submodule 67 and a central connector 62 positioned on the rear plate, where this connection may be made easily and rapidly.

This assembly forms a rigid self-supporting module, with 6 working faces.

As illustrated in FIGS. 8 and 9, the overhead panel of the invention is, through its peripheral electrical connectors 63, connected to:
connections 75 entitled “Route M” (where M stands for “average”), which are low-power cables requiring no substantial protection (conventional functions),
connections 76 entitled “Route S” (where S stands for “sensitive”), which are coaxial cables, which are segregated separately.

In these figures a pipe 77 for extracting heat energy produced by the overhead panel, and two air conditioning pipes 78, each of which is terminated by an air outlet to convey fresh air to the cockpit, which are not connected to the overhead panel of the invention, but which pass close by it, are also represented.

As illustrated in these figures, four dampening pins 80 are positioned at all four corners of the rear surface of the rear plate of the overhead panel of the invention.

The metal sheet forming the front plate may be pierced with weight reduction and accessibility holes. The front face of the front plate, which corresponds to the different represented systems and functions of the aeroplane, is fixed for an aeroplane programme, in order that it may be easily understood by the pilots.

Advantageously, the rear plate includes an integrated circuit which resists condensation. To this end it may include a final specific layer, or be positioned on a small panel made of a thermoplastic material.

As illustrated in FIG. 10, the overhead panel of the invention 60 is positioned on small intermediate brackets 81 attached to the structure of the aeroplane 82 (reference 83 represents the aeroplane's aerodynamic profile), where four dampening pins 80 are positioned between the rear surface of the rear plate and these intermediate brackets 81.

The assembly of the overhead panel of the invention includes the following steps illustrated in FIGS. 11A to 11G:

1. integration of mini-harnesses 72 on submodules 67, for example action buttons or lights (FIG. 11A),

2. clipping of these mini-harnesses 72 on the corresponding central connectors 62 previously welded on the integrated circuit plate of rear plate 61 (FIG. 11B),

3. attachment of the assembly formed in this manner to perimeter frame 70 (FIG. 11C),

4. docking of front plate 65, ensuring that each of submodules 67 is centred in a corresponding recess of the front plate. Advantageously, the perimeter frame and the front plate are locally perforated, enabling the objects to be recentred more easily in their recesses using tools if required (FIG. 11D),

5. attachment of submodules 67, for example action buttons, on front plate 65 (FIG. 11E),

6. installation and attachment of illuminated label 66 (FIG. 11F).

FIG. 11G illustrates the assembly of overhead panel 60 ready to be installed in the cockpit of an aeroplane.

1. An overhead panel able to be positioned in an aircraft cockpit, wherein it includes an assembly of independent submodules, each of which is associated with a particular system or a particular function of the aeroplane, incorporated in a rigid self-supporting module, including a front face to which the submodules are attached, and two side faces fitted with peripheral electrical connectors intended to be connected to different systems of the aeroplane.

2. An overhead panel according to claim 1, in which the rigid self-supporting module is parallelepipedic in shape and less than 100 mm thick.

3. An overhead panel according to claim 1, in which the module includes:
a rear plate including an integrated circuit plate to which central electrical connectors and the peripheral electrical connectors are welded,
a front plate, to which the submodules are attached,
a perimeter frame forming the junction between these two rear and front plates, over entire periphery of the module;
micro-harnesses, each making a connection between a submodule and a central connector positioned on the rear plate.

4. A panel according to claim 3, in which an illuminated label is positioned on the front plate.

5. An overhead panel according to claim 1, in which the front plate includes a metal sheet in which weight reduction and accessibility holes are made.

6. An overhead panel according to claim 3 including dampening pins positioned on the rear surface of the rear plate.

7. An overhead panel according to claim 3, in which the rear plate includes an integrated circuit plate the final layer of which is a specific anti-condensation layer.

8. An overhead panel according to claim 3, in which the rear plate includes a small panel made of thermoplastic anti-condensation material.

9. A method for manufacturing the overhead panel according to claim 3, which includes:
integration of mini-harnesses on the submodules,
clipping of these mini-harnesses on the corresponding central connectors previously welded on the integrated circuit plate of rear plate,
attachment of the assembly formed in this manner to the perimeter frame,
docking of the front plate, ensuring that each of submodules is centred in a corresponding recess of the front plate,
attachment of the submodules on the front plate.

10. An aircraft including a cockpit in which an overhead panel according to claim 1 is installed.
